(19) United States
(12) Patent Application Publication
(10) Pub. No.: US 2026/0262470 A1
(43) Pub. Date: Sep. 3, 2026

(54) WAFER PLACEMENT SENSORS FOR SUBSTRATE RINSE SYSTEM

(71) Applicant: Applied Materials, Inc., Santa Clara, CA (US)

(72) Inventor: Nolan L. Zimmerman, Kalispell, MT (US)

(73) Assignee: Applied Materials, Inc., Santa Clara, CA (US)

(21) Appl. No.: 19/067,076

(22) Filed: Feb. 28, 2025

(51) Int. Cl. H01L 21/68; G01S 15/08; G01V 8/22; H01L 21/67

(52) U.S. Cl. CPC H10P 72/53; G01S 15/08; G01V 8/22; H10P 72/0411

(57) ABSTRACT

Exemplary substrate rinsing assemblies may include a rotor. The assemblies may include a plurality of substrate-grasping fingers disposed on the rotor. Each of the plurality of substrate-grasping fingers may be moveable between an open position and a closed position. An ultrasonic sensor may be disposed above the rotor at a position that is radially inward of the plurality of substrate-grasping fingers. The ultrasonic sensor may be configured to detect whether a position of a substrate received by the plurality of substrate-grasping fingers is within a predetermined operational range. The assemblies may include a plurality of reflective sensors. Each of the plurality of reflective sensors may be aligned with a respective one of the plurality of substrate grasping fingers. Each of the plurality of reflective sensors may be configured to detect whether the respective one of the plurality of substrate-grasping fingers is in the open position or the closed position.

### TECHNICAL FIELD

The present technology relates to semiconductor systems, processes, and equipment. More specifically, the present technology relates to substrate rinse assemblies that are used to clean substrates after various processing operations.

### BACKGROUND

Microelectronic devices, such as semiconductor devices, are fabricated on and/or in wafers or workpieces. A typical wafer plating process involves depositing a metal seed layer onto the surface of the wafer via vapor deposition. A photoresist may be deposited and patterned to expose the seed layer. The wafer is then moved into the vessel of an electroplating processor where electric current is conducted through an electrolyte to the wafer, to apply a blanket layer or patterned layer of a metal or other conductive material onto the seed layer. Examples of conductive materials include permalloy, gold, silver, copper, cobalt, tin, nickel, and alloys of these metals. Subsequent processing steps form components, contacts and/or conductive lines on the wafer. Many aspects of an electroplating process may impact process uniformity, such as irregularities in the electric field due to pattern variations, mass-transfer rates, as well as other process and component parameters. Even minor discrepancies across a substrate may impact downline finishing processes.

After a given plating operation, some residual amount of electrolyte or other plating solution may remain on a surface of the wafer. This plating solution may cause issues in subsequent plating or other processing operations. Therefore, the wafer is often transferred to a rinse assembly after plating. In some instances, during the transfer of the wafer, the wafer may be misaligned within the rinse assembly and/or fingers that hold the wafer to a rotor of the rinse assembly may malfunction. The misalignment or malfunctioning of the fingers may cause damage to the wafer.

Thus, there is a need for improved systems and methods that can be used minimize damage to the wafer during rinse operations. These and other needs are addressed by the present technology.

### SUMMARY

Exemplary substrate rinsing assemblies may include a rotor. The assemblies may include a plurality of substrate-grasping fingers disposed on the rotor. Each of the plurality of substrate-grasping fingers may be moveable between an open position and a closed position. An ultrasonic sensor may be disposed above the rotor at a position that is radially inward of the plurality of substrate-grasping fingers. The ultrasonic sensor may be configured to detect whether a position of a substrate received by the plurality of substrate-grasping fingers is within a predetermined operational range. The assemblies may include a plurality of reflective sensors. Each of the plurality of reflective sensors may be aligned with a respective one of the plurality of substrate grasping fingers. Each of the plurality of reflective sensors may be configured to detect whether the respective one of the plurality of substrate-grasping fingers is in the open position or the closed position.

In some embodiments, each of the plurality of reflective sensors may include a beam emitter that emits light and a receiver. Detecting the respective one of the plurality of substrate-grasping fingers is in the open position or the closed position may include determining an intensity of the light reflected back from the respective one of the plurality of substrate-grasping fingers and received by the receiver. The beam emitter may be aligned with a top surface of the respective one of the plurality of substrate-grasping fingers when in the closed position. The assemblies may include a plurality of splash guards. Each splash guard may be positioned about one of the plurality of reflective sensors. Each splash guard may extend at least 0.5 inches below a base of the one of the plurality of reflective sensors. The ultrasonic sensor may be disposed within an outer 25% of distance from a center of the rotor to the plurality of substrate-grasping fingers. The ultrasonic sensor may be disposed within an outer 5% of distance from a center of the rotor to the plurality of substrate-grasping fingers. The assemblies may include a rinse arm that extends over a rotor. The rinse arm may include a fluid nozzle that is positioned between the plurality of substrate-grasping fingers.

Some embodiments of the present technology may encompass substrate rinsing assemblies. The assemblies may include a rotor and a plurality of substrate-grasping fingers disposed on the rotor. Each of the plurality of substrate-grasping fingers may be moveable between an open position and a closed position. The assemblies may include an ultrasonic sensor disposed above the rotor at a position that is radially inward of the plurality of substrate-grasping fingers. The assemblies may include a plurality of reflective sensors. Each of the plurality of reflective sensors may be aligned with a respective one of the plurality of substrate grasping fingers. The assemblies may include one or more processors that are configured to determine whether a position of a substrate received by the plurality of substrate-grasping fingers is within a predetermined operational range based on a measurement from the ultrasonic sensor. The one or more processors may be configured to determine whether the respective one of the plurality of substrate-grasping fingers is in the open position or the closed position based on a signal from each of the plurality of substrate-grasping fingers.

In some embodiments, the one or more processors may be further configured to, prior to receiving the substrate, confirm that each of the plurality of substrate-grasping fingers is in the open position. The one or more processors may be further configured to, upon receiving the substrate, cause the each of the plurality of substrate-grasping fingers to move to the closed position. The one or more processors may be further configured to confirm that each of the plurality of substrate-grasping fingers is in the closed position. The one or more processors may be further configured to, upon confirming that each of the plurality of substrate-grasping fingers is in the closed position, adjust an angular position of the rotor to sequentially align each of the plurality of substrate-grasping fingers with the ultrasonic sensor. The one or more processors may be further configured to receive a measurement from the ultrasonic sensor at each angular position of the plurality of substrate-grasping fingers. Determining whether a position of a substrate received by the plurality of substrate-grasping fingers is within a predetermined operational range may be performed based on the measurements at each angular position of the plurality of substrate-grasping fingers. The one or more processors may be further configured to, upon confirming that each of the plurality of substrate-grasping fingers is in the closed position and that the position of the substrate is within the predetermined operational range, perform a rinse operation on the substrate. The one or more processors may be further configured to, upon completion of the rinse operation, confirm that the position of the substrate is still within the predetermined operational range. The one or more processors may be further configured to, upon confirming that the position of the substrate is still within the predetermined operational range, cause the each of the plurality of substrate-grasping fingers to move to the open position. The one or more processors may be further configured to confirm that each of the plurality of substrate-grasping fingers is in the open position. The one or more processors may be further configured to generate an alarm based on one or both of determining that a position of a substrate received by the plurality of substrate-grasping fingers is outside the predetermined operational range and determining that at least one of the plurality of substrate-grasping fingers is in an incorrect position.

Some embodiments of the present technology may encompass methods of rinsing a semiconductor substrate. The methods may include receiving a substrate within a plurality of substrate-grasping fingers of a rotor. The methods may include determining whether a position of the substrate is within a predetermined operational range based on a measurement from an ultrasonic sensor disposed above the rotor. The methods may include determining whether the respective one of the plurality of substrate-grasping fingers is in an open position or a closed position based on a signal from each of the plurality of substrate-grasping fingers.

In some embodiments, the methods may include, prior to receiving the substrate, confirming that each of the plurality of substrate-grasping fingers is in the open position. The methods may include, upon receiving the substrate, moving each of the plurality of substrate-grasping fingers to move to the closed position. The methods may include confirming that each of the plurality of substrate-grasping fingers is in the closed position. The methods may include, upon confirming that each of the plurality of substrate-grasping fingers is in the closed position, adjusting an angular position of the rotor to sequentially align each of the plurality of substrate-grasping fingers with the ultrasonic sensor. The methods may include receiving a measurement from the ultrasonic sensor at each angular position of the plurality of substrate-grasping fingers. Determining whether a position of a substrate received by the plurality of substrate-grasping fingers is within a predetermined operational range may be performed based on the measurements at each angular position of the plurality of substrate-grasping fingers. The methods may include, upon confirming that each of the plurality of substrate-grasping fingers is in the closed position and that the position of the substrate is within the predetermined operational range, perform a rinse operation on the substrate. The methods may include, upon completion of the rinse operation, confirming that the position of the substrate is still within the predetermined operational range. The methods may include, upon confirming that the position of the substrate is still within the predetermined operational range, moving each of the plurality of substrate-grasping fingers to the open position. The methods may include confirming that each of the plurality of substrate-grasping fingers is in the open position. The methods may include transferring the substrate from the plurality of substrate-grasping fingers. The methods may include generating an alarm based on one or both of determining that a position of a substrate received by the plurality of substrate-grasping fingers is outside the predetermined operational range and determining that at least one of the plurality of substrate-grasping fingers is in an incorrect position.

Such technology may provide numerous benefits over conventional systems and techniques. For example, the present technology may provide sensors that enable the position of the substrate within a rinse assembly and/or an operational status of substrate-grasping fingers to be confirmed prior to operation of a rinse system. This may help prevent damage to the substrate and/or rinse system and may reduce system downtime. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top perspective view of an exemplary substrate rinsing system according to some embodiments of the present technology.

FIG. 1A shows a partial side elevation view of a reflective sensor and substrate-grasping finger of the substrate rinsing system of FIG. 1.

FIG. 1B shows a partial side elevation view of a reflective sensors and substrate-grasping finger of the substrate rinsing system of FIG. 1.

FIG. 1C shows a partial side elevation view of an ultrasonic sensor and substrate of the substrate rinsing system of FIG. 1.

FIG. 1D shows a partial top perspective view of a reflective sensor and splash guard of the substrate rinsing system of FIG. 1.

FIG. 1E shows a partial side elevation view of a reflective sensor and splash guard of the substrate rinsing system of FIG. 1.

FIG. 2 shows operations of a method of rinsing a substrate according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In many or most electroplating applications, it is important that the plated film or layer(s) of metal have a uniform thickness across the wafer or workpiece. Non-uniformities can be caused by irregularities in the electric field due to pattern variations, by mass-transfer rates, and/or other factors. For example, uniformity issues may arise when residual amounts of an electrolyte or other plating solution remains on the wafer after one or more plating operations. To address such issues, conventional plating systems include rinse assemblies that may rinse any residual plating solution from the surface of the wafer after and/or in between one or more plating operations. However, misalignment of the wafer within the rinse assembly or malfunctioning of the fingers used to hold the wafer to a rotor of the rinse assembly may cause damage to the wafer. The damage to the wafer may render it unusable, while broken pieces of the wafer may cause additional damage to the rinse assembly.

The present technology overcomes these challenges by incorporating sensors that detect whether the wafer is properly positioned within the rinse assembly and whether the fingers are properly functioning. For example, embodiments of the present technology may utilize an ultrasonic sensor that is able to detect a height of the wafer at various angular positions to ensure that the wafer is properly seated within the fingers and does not have an unacceptable degree of wafer bowing. Additional sensors may be integrated into the rinse assembly that determine whether the individual fingers are functioning properly. For example, optical sensors may be used to determine whether the fingers are in a proper open or closed state at various points of operation of the rinse assembly. Together, the ultrasonic sensors and optical finger sensors may ensure that the wafer is properly positioned within the rinse assembly, does not have an excessive degree of bowing, and that the fingers are in a correct position to constrain or receive a wafer at various points in the wafer transfer and rinse processes. Alarms may be triggered when any of these conditions are not met, which may help prevent wafer and system damage. Accordingly, the present technology may more safely handle wafers during rinse operations.

Although the remaining disclosure will routinely identify specific rinse processes utilizing the disclosed technology, it will be readily understood that the systems and methods are equally applicable to other plating chambers and systems, as well as processes as may occur in the described systems. For example, rinsing occurring at other processing stages (such as, but not limited to, after polishing operations) may utilize the sensor arrangements described herein. Accordingly, the technology should not be considered to be so limited as for use with these specific rinsing processes or systems alone. The disclosure will discuss one possible system that may include rinsing components according to embodiments of the present technology before additional variations and adjustments to this system according to embodiments of the present technology are described.

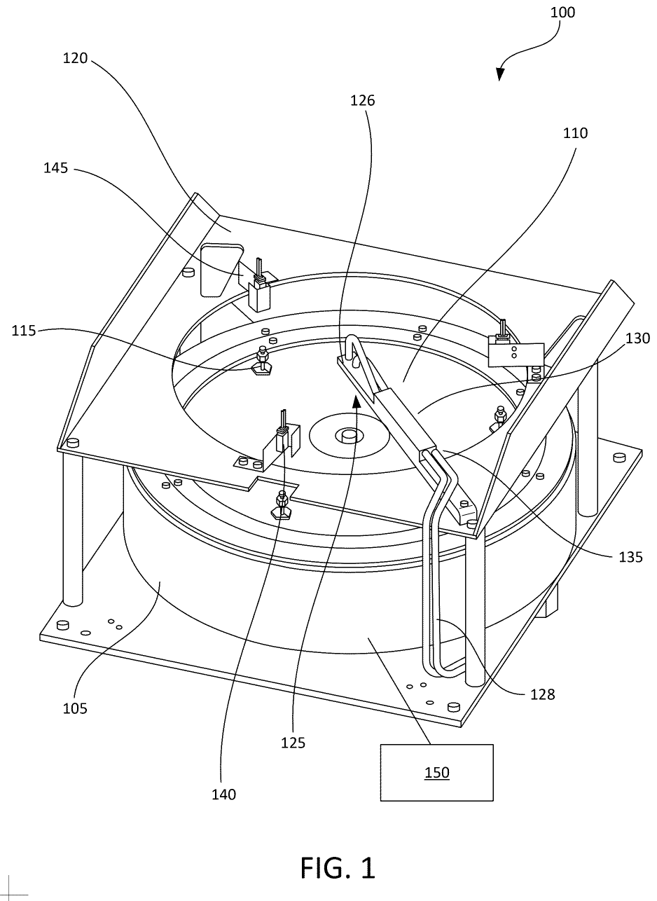

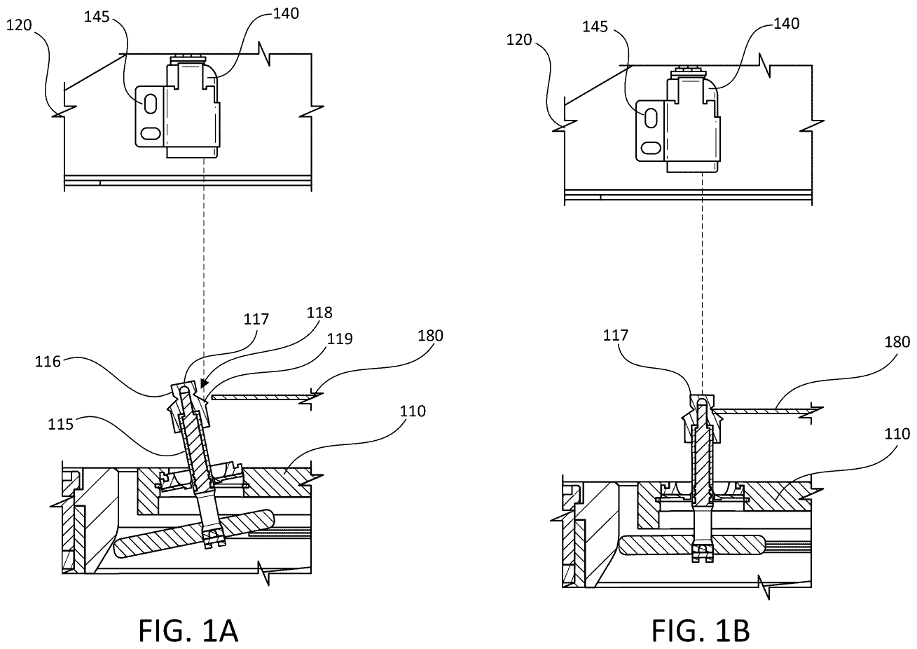

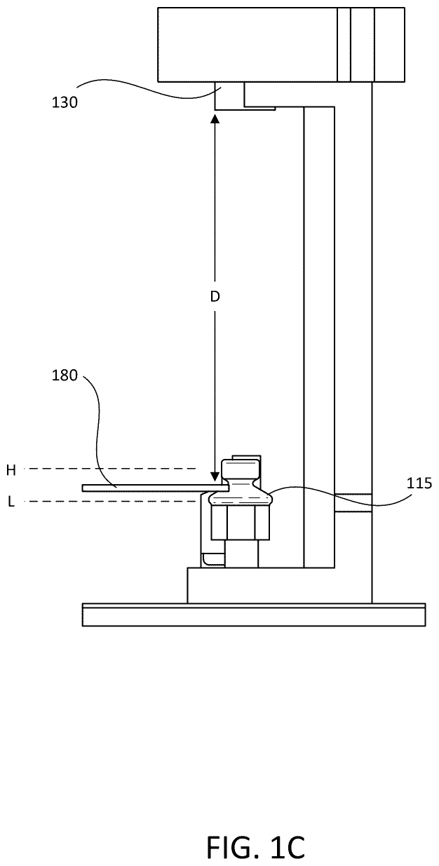

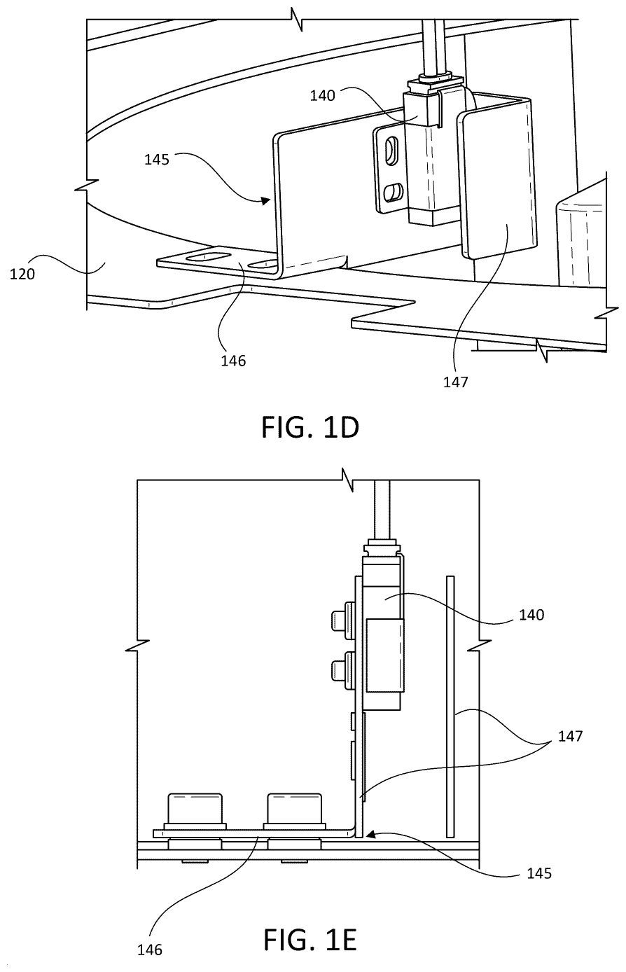

FIG. 1 shows a illustrates a schematic partial cross-sectional side elevation view of an exemplary substrate rinsing system 100 according to some embodiments of the present technology. The rinsing system 100 may show a partial view of the components being discussed and may include additional features not illustrated here. The rinsing system 100 may include a load cup 105 that may receive a substrate, as well as a rinse solution that may be delivered to a surface of the substrate during rinse operations. A rotor 110 may be disposed within an open interior of the load cup 105. The rotor 110 may be coupled with a motor (not shown) that may rotate the rotor 110 within the load cup 105. Rotation of the rotor 110 may enable the substrate to be rotated to evenly expose the surface of the substrate to a rinse solution. Additionally, rotation of the rotor 110 may enable the rinsing system 100 to ensure that the substrate is properly aligned for transfer and rinse operations, as will be discussed in greater detail below.

A number of substrate-grasping fingers 115 may be disposed on the rotor 110. For example, each substrate-grasping finger 115 may be disposed at a different angular position about the rotor 110, with each substrate-grasping finger 115 being at a same radial distance from a center of the rotor 110. In some embodiments, the substrate-grasping fingers 115 may be arranged at equal angular intervals about the center of the rotor 110, while in other embodiments some or all of the substrate-grasping fingers 115 may be arranged at irregular angular intervals. While shown here with three substrate-grasping fingers 115, other numbers of substrate-grasping fingers 115 may be included in various embodiments. For example, the rotor 110 may include three or more substrate-grasping fingers 115, four or more substrate-grasping fingers 115, five or more substrate-grasping fingers 115, six or more substrate-grasping fingers 115, eight or more substrate-grasping fingers 115, ten or more substrate-grasping fingers 115, or more.

As best illustrated in FIGS. 1A and 1B, each substrate-grasping finger 115 may include a cap or top end 116 that may include a top surface 117. The top end 116 may include a groove 118 that is sized to receive a peripheral edge of a substrate 180 when the substrate-grasping fingers 115 are in the closed position (as shown in FIG. 1B). The top end 116 may include a tapered portion 119 just below and leading up to the groove 118. The tapered portion 119 may help enable the substrate-grasping fingers 115 to properly center the substrate once the substrate is received on the substrate-grasping fingers 115 and the substrate-grasping fingers 115 are closed. The top end 116 of the substrate-grasping finger 115 may be formed integrally with a body or stem of the substrate-grasping finger 115 or may be a separate component that is coupled with the stem of the substrate-grasping finger 115. The top end 116 may be formed from a material that is compatible with the rinse solution and that will not scratch or otherwise damage the substrate. For example, in some embodiments the top end 116 may be formed from a polymeric material such as, but not limited to, PEEK, polyvinylidene fluoride, polypropylene, etc.

Each substrate-grasping finger 115 may be moveable between an open position and a closed position. For example, as shown in FIG. 1A, when the substrate-grasping finger 115 is in the open position, a stem of the substrate-grasping finger 115 is tilted or otherwise translated radially outward relative to the center of the rotor 110. In the open position, at least a portion of the top end 116 above the groove 118 of the substrate-grasping finger 115 may be positioned radially outward of a peripheral edge of the substrate, which may provide clearance for the substrate to be transferred to or from the rotor 110. As shown in FIG. 1B, when the substrate-grasping finger 115 is in the closed position, the stem of the substrate-grasping finger 115 is tilted or otherwise translated radially inward relative to the center of the rotor 110. In the closed position, at least a portion of the top end 116 extends radially inward of a peripheral edge of the substrate, which enables the substrate to be secured to the rotor 110. For example, the tapered portion 119 and a portion of the top end 116 that is above the groove 118 may extend radially inward of the peripheral edge of the substrate such that the substrate is seated within the groove 118. The tapered portion 119 and the portion of the top end 116 that is above the groove 118 may constrain movement of the substrate in a vertical direction, while the presence of three or more substrate-grasping fingers 115 positioned about the substrate may constrain movement of the substrate in a horizontal direction. When the substrate is secured within the substrate-grasping fingers 115 in the closed position, rotation of the rotor 110 may cause a corresponding rotation of the substrate.

In some embodiments, one or more fixed substrate supports (not shown) may be disposed on the rotor 110 to support the bottom and/or peripheral edge of the substrate when the substrate-grasping fingers 115 are in the open position. In some embodiments, in the open position, a portion of the tapered portion 119 may remain below the peripheral edge of the substrate when the substrate-grasping fingers 115 are in the open position, enabling the substrate-grasping fingers 115 to support the substrate even while in the open position.

The rinsing system 100 may include one or more elevated support structures 120 that may each support one or more components above the load cup 105. In some embodiments, each component may have a dedicated support structure 120, while in other embodiments multiple (and possibly all) components may share a single support structure 120. As illustrated, the support structure 120 supports a rinse assembly 125 at a position that is above the load cup 105. The rinse assembly 125 may include a rinse arm 126 that extends radially inward from the support structure 120 such that at least a portion of the rinse arm 126 extends over the rotor 110. The rinse arm 126 may include one or more fluid nozzles that are positioned above the rotor 110 and between the substrate-grasping fingers 115 (or otherwise positioned and oriented to direct a rinsing fluid into the region between the substrate-grasping fingers 115). For example, in some embodiments the fluid nozzles may be positioned at or near a distal end of the rinse arm 126 and may direct the rinse fluid to a surface of the substrate. The fluid nozzles may be fluidly coupled with a fluid source (not shown) via one or more fluid lines 128. The fluid source may store a rinse solution for delivery to the surface of the substrate. The rinse solution may include a liquid that may rinse any remaining electrolyte or other residual material from the surface of the substrate without damaging the substrate. For example, in some embodiments, the rinse solution may include deionized water, acidic solutions, basic solutions, a cleaning chemistry, and/or other substrate-compatible liquid. The rinse assembly 125 may include a pump or other fluid flow device (not shown) that may help facilitate flow of the rinse solution to the fluid nozzle.

The rinse system 100 may include an ultrasonic sensor 130 disposed above the rotor 110. For example, the ultrasonic sensor 130 may be coupled with the support structure 120 via a bracket 135 or other mounting device that positions the ultrasonic sensor 130 above the rotor 110 and at a position that is radially inward of the of substrate-grasping fingers 115. The ultrasonic sensor 130 may be configured to detect whether a position of a substrate received by the substrate-grasping fingers 115 is within a predetermined operational range. For example, a transducer of the ultrasonic sensor may transmit one or more ultrasonic waves toward the rotor 110. When the waves contact the surface of the substrate supported atop the rotor 110, the waves are reflected back toward the ultrasonic sensor 130. The transducer of the ultrasonic sensor 130 receives the reflected waves and may determine a distance to the substrate by measuring time lapses between the transmission and reception of the waves. A processor of the rinse system 100 may be trained or otherwise programmed with a predetermined operational range of positions of the substrate. The processor may compare the position of the substrate as detected by the ultrasonic sensor 130 to preset targets to determine whether the substrate is properly seated within the substrate-grasping fingers 115. For example, the predetermined operating range may include a highest position on the substrate-grasping fingers 115 and a lowest position on the substrate-grasping fingers 115 at which the substrate may be supported without risking damage to the substrate. The predetermined operating range may also take into account an acceptable level of substrate bowing, which may occur, for example, due to stresses imparted on the substrate by deposited film and/or plating layers. The controller may determine that the position of the substrate is within the predetermined operational range based on measurements from the ultrasonic sensor 130 at a number of discrete angular positions of the substrate. The angular positions may be in alignment or substantial alignment with the substrate-grasping fingers 115. For example, the measurements of the position of the substrate may be taken at angular locations that are within 10 degrees of an substrate-grasping finger 115, within 5 degrees of an substrate-grasping finger 115, within 3 degrees of an substrate-grasping finger 115, within 1 degree of an substrate-grasping finger 115, within 0.5 degrees of an substrate-grasping finger 115, or less (such as exactly aligned with an substrate-grasping finger 115). As illustrated in FIG. 1C, based on the distance D between the ultrasonic sensor 130 and the substrate 180 at each angular position, the controller may determine an orientation of the substrate. For example, if all of the distances are the same, the substrate may be seated in a perfectly horizontal position within the substrate-grasping fingers 115. If some distances are high and others are low (e.g., in relation to a predetermined high threshold H and low threshold L), the substrate may be tilted on the substrate-grasping fingers 115 and/or may have a noticeable degree of bowing. Similarly, if a distance measurement is too high or too low, it may indicate that the substrate is broken, excessively bowed, and/or incorrectly positioned relative to the substrate-grasping fingers 115 (e.g., a portion of the substrate is angled toward and/or is in contact with the rotor 110 while another portion of the substrate is lifted off (e.g., above) a respective substrate-grasping finger 115). In this manner, the controller may compare the distance measurements from the ultrasonic sensor 130 to predetermined ranges to determine if the substrate is properly positioned and/or has an acceptable degree of bowing.

Due to the geometry of the substrate and placement of the substrate-grasping fingers 115, the most accurate region to position the ultrasonic sensor 130 for measuring the substrate position may be within the outer regions of the substrate, as a smaller working range of distances is needed to determine whether the substrate can be securely seated within the substrate-grasping fingers 115 at such locations. Additionally, in situations where a substrate is tilted downward from one end to another (e.g., one end of the substrate is positioned above a substrate-grasping finger 115 and the other end is positioned below a substrate-grasping finger 115 and proximate the surface of the rotor 110), the middle of the substrate may be in approximately the correct position despite the edges of the substrate being significantly out of position. Therefore, the bracket 135 may be sized and positioned such that the ultrasonic sensor 130 is positioned within an outer 50% of the distance from the center of the rotor 110 to the substrate-grasping fingers 115, within an outer 40% of the distance, within an outer 30% of the distance, within an outer 25% of the distance, within an outer 20% of the distance, within an outer 15% of the distance, within an outer 10% of the distance, within an outer 5% of the distance, within an outer 3% of the distance, within an outer 1% of the distance, or less. However, in some embodiments, the ultrasonic sensor 130 may be positioned at a more radially inward location (e.g., within an inner 50% of the distance).

The rinsing system 100 may include a number of reflective sensors 140 that may be positioned above the load cup 105. For example, the reflective sensor 140 may be positioned on the support structure 120 at radial positions that are aligned or substantially aligned (e.g., within 10 degrees) with the substrate-grasping fingers 115. Each reflective sensor 140 may be configured to detect whether the respective one of the substrate-grasping fingers 115 is in the open position or the closed position. In some embodiments, each substrate-grasping finger 115 may include a dedicated reflective sensor 140 such that a number of the reflective sensors 140 matches the number of substrate-grasping fingers 115. Each reflective sensor 140 may include a beam emitter (such as a light emitting diode (LED) or other light source) that emits light and a receiver. The beam emitter may be oriented such that at least a portion of the light is directed toward the top surface 117 of a given substrate-grasping finger 115. In some embodiments, each reflective sensor 140 may be positioned directly above the substrate-grasping finger 115 such that the beam emitter is oriented perfectly vertically, however, slight offsets are possible in some instances. In some embodiments, the light emitted by the beam emitter may be very focused, which may ensure that all or substantially all of the light emitted by the beam emitter is directed onto the top surface 117 of a given substrate-grasping finger 115. The receiver may be a photosensor, photodetector, or other optical sensor that detects light reflected back.

In some embodiments, the reflective sensor 140 may be a diffuse-reflective sensor. In such embodiments, the receiver detects light reflected back from the substrate-grasping finger 115. In some such embodiments, the beam emitter may be positioned such that the emitted light is concentrated on the top surface of a substrate-grasping finger 115 when the substrate-grasping finger 115 is in a closed position (such as shown in FIG. 1B) and is concentrated on a different region of the substrate-grasping finger 115 and/or rotor 110 when in the open position (such as shown in FIG. 1A). For example, in such embodiments the light emitted by the beam emitter will reflect differently from the top surface 117 of the substrate-grasping finger 115 (e.g., when the substrate-grasping finger 115 is in the closed position) than on the other portion of the substrate-grasping finger 115 and/or rotor 110 (e.g., when the substrate-grasping finger 115 is in the open position). This difference in reflection results in a different light intensity being measured by the receiver, which enables the reflective sensor 140 to determine whether the substrate-grasping finger 115 is in the open or closed position. In some embodiments, the positioning of the reflective sensor 140 may be switched such that the emitted light is concentrated on the top surface of a substrate-grasping finger 115 when the substrate-grasping finger 115 is in the open position and is concentrated on a different region of the substrate-grasping finger 115 and/or rotor 110 when in the closed position. For example, movement of the substrate-grasping finger 115 from the closed position to the open position may cause the top surface 117 of the substrate-grasping finger 115 to be moved into the emission field of the light emitter. In such embodiments, a similar change in measured light intensity from the reflected light may be used to determine whether the substrate-grasping finger 115 is in the open or closed position.

In some embodiments, the reflective sensor 140 may be a retro-reflective sensor that includes a separate retroreflector. For example, the beam emitter may be positioned to emit light toward a retroreflector that is positioned radially outward of the top end 116 of the substrate-grasping finger 115 when the substrate-grasping finger 115 is in the closed position. When the substrate-grasping finger 115 is in the closed position, the light emitted from the beam emitter may be reflected back by the retroreflector and received by the receiver of the reflective sensor 140. When the substrate-grasping finger 115 moves to the open position, the top end 116 of the substrate-grasping finger 115 may obstruct or otherwise interrupt the path between the beam emitter and the retroreflector. Based on the change in intensity of reflected light detected by the receiver (e.g., the difference between the reflectance of the retroreflector and the top surface 117 of the substrate-grasping finger 115), the reflective sensor 140 may determine that the substrate-grasping finger 115 is in the open position.

In some embodiments, through-beam sensors may be used. For example, the reflective sensor 140 may include a beam emitter that emits a beam of light toward a receiver positioned radially outward of the top end 116 of the substrate-grasping finger 115 when the substrate-grasping finger 115 is in the closed position. When the substrate-grasping finger 115 is in the closed position, the light emitted from the beam emitter may be received by the receiver. When the substrate-grasping finger 115 moves to the open position, the top end 116 (or other portion) of the substrate-grasping finger 115 may obstruct or otherwise interrupt the path between the beam emitter and the receiver and prevent the light from reaching the receiver. When no light is detected by the receiver, the reflective sensor 140 may determine that the substrate-grasping finger 115 is in the open position.

While described as utilizing reflective sensors and ultrasonic sensors, it will be appreciated that other forms for sensors may be used to detect the position of the substrate and/or the open/close state of the substrate-grasping fingers 115. For example, the sensors may other optical sensors, including laser proximity sensors (e.g., light detection and ranging (LiDAR), etc.), other sound wave proximity sensors, and/or other position sensors. In some embodiments, certain sensor types and coupling mechanisms may be particularly beneficial as they enable existing rinse systems to be retrofitted with substrate position sensors (e.g., the ultrasonic sensor 130) and/or substrate-grasping finger 115 sensors (e.g., reflective sensors 140). For example, the use of diffuse-reflective sensors may enable the reflective sensors 140 to be mounted above the substrate-grasping fingers 115 without the need to add retroflectors or receivers proximate a base of the substrate-grasping fingers 115, which may otherwise require a substantial modification to the design of the rotor 110. Similarly, by mounting the ultrasonic sensor 130 to the support structure 120 via the bracket 135, rather than coupling the ultrasonic sensor 130 to the rinse arm 126 or other existing structure extending over the rotor 110, as such coupling may require modification to the rinse arm 126.

The rinse system 100 may include a number of splash guards 145. As best illustrated in FIGS. 1D and 1E, each splash guard 145 may be positioned about one of the plurality of reflective sensors. The splash guards 145 may include mounting brackets 146 that may couple the splash guards 145 with the support structure 120. The mounting bracket 146 may be fastened or otherwise secured to the support structure 120, such as via one or more fasteners. The splash guards 145 may include one or more vertical walls 147 that extend around one or more sides of the reflective sensor 140. For example, as illustrated, the vertical walls 147 may form a generally U-shaped structure that extends about the three sides of the reflective sensor 140 facing the load cup 105, leaving only the radially outward-facing side of the reflective sensor 140 exposed. In some embodiments, the reflective sensor 140 may be secured to one or more of the vertical walls 147 of the splash guard 145 to maintain the reflective sensor 140 in position relative to the rotor 110.

The splash guards 145 may be sized and positioned to block any spray that is generated from the rinse process, such as spray that comes up from the substrate and/or the load cup 105. For example, in rinse assemblies in which the rotor 110 is rotatable in only a single direction, one or more vertical walls 147 of the splash guard 145 may extend downward on a side of the reflective sensor 140 that is between a direction of rotation of the rotor 110 and the reflective sensor 140. Where the rotor 110 is capable of rotating in both directions, the vertical walls 147 of the splash guard 145 may extend downward on both sides of the reflective sensor 140 that are between a direction of rotation of the rotor 110 and the reflective sensor 140. Vertical walls 147 of each splash guard 145 may extend downward beyond a bottom end of the reflective sensor 140 a distance to prevent the splashed rinse solution from reaching the reflective sensor 140, which may depend on a variety of factors, such as a vertical distance between the reflective sensor 140 and the substrate and/or load cup 105, a speed of rotation of the rotor 110, a size of the substrate and/or load cup 105, a volume and/or flow rate of the rinse solution, a viscosity of the rinse solution, and/or other variables. In some embodiments, the vertical walls 147 of each splash guard 145 may extend downward beyond a bottom end of the reflective sensor 140 by a distance of at least 0.25 inches, at least 0.5 inches, at least 0.75 inches, at least 1 inch, at least 1.25 inches, at least 1.5 inches, or more.

The operation of the rinsing system 100 may be controlled by a computer system 150. The computer system 150 may include any device or combination of devices configured to implement the operations described below. Accordingly, the computer system 150 may be a controller or array of controllers and/or a general purpose computer configured with software stored on a non-transitory, computer-readable medium that, when executed, may perform the operations described in relation to methods according to embodiments of the present technology. The rinsing may be configured to perform one or more process operations in the fabrication of a semiconductor structure. More specifically, the rinsing chambers may be outfitted to remove undesired material from the surface of the substrate after various processing operations, such as (but not limited to) electroplating operations and polishing operations.

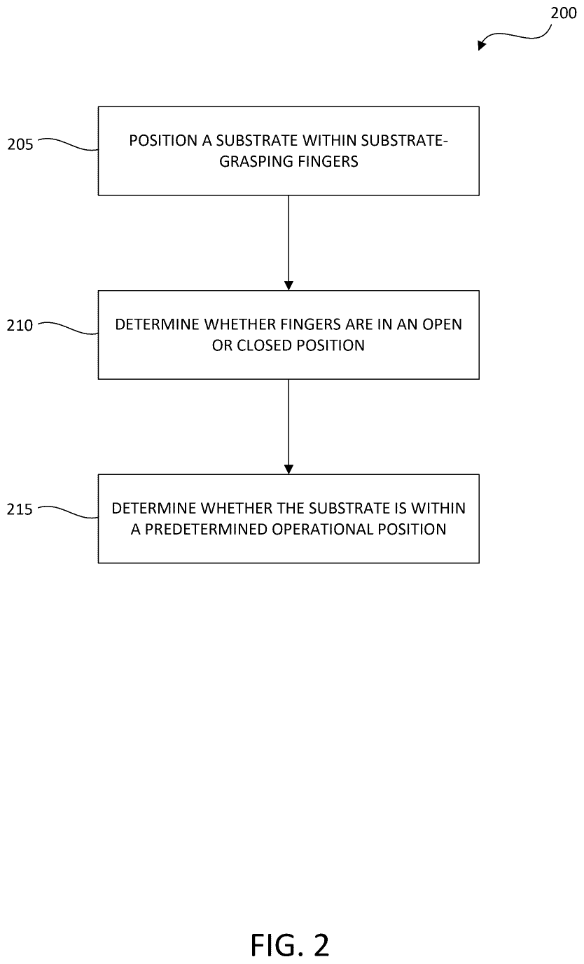

FIG. 2 shows exemplary operations in a method 200 for rinsing a surface of a substrate according to some embodiments of the present technology. Method 200 may be performed using a rinsing system such as rinsing system 100 described herein. Method 200 may include operations prior to the substrate rinsing in some embodiments. For example, prior to the rinsing, a substrate may have one or more polishing operations performed as well as any deposition, etch, or other process operations performed. Method 200 may include a number of operations that may be performed automatically within a system to limit manual interaction, and to provide increased efficiency and precision over manual operations. Method 200 may be performed as part of or in conjunction with a conventional substrate rinsing process.

Method 200 may include receiving a substrate within a number of substrate-grasping fingers of a rotor, such as substrate-grasping fingers 115 of rotor 110, at operation 205. The substrate may be positioned within the substrate-grasping fingers by a transfer robot. In some embodiments, prior to receiving the substrate, the method 200 may include confirming that each of the substrate-grasping fingers is in the open position. For example, measurements from reflective sensors (e.g., reflective sensors 140) associated with each of the substrate-grasping sensor may be used to determine whether the substrate-grasping sensor is in the open position to the closed position at operation 210. For example, in some embodiments, the measurement may include measuring an intensity of light reflected back to the reflective sensor from the substrate-grasping finger and/or rotor as discussed above in connection with FIGS. 1-1B. Upon receiving the substrate, each of the substrate-grasping finger may be moved to the closed position. Subsequently, the method may include confirming that each of the substrate-grasping fingers is in the closed position. This may be done in a similar manner as described above with respect to determine whether the substrate-grasping sensor is in the open position.

Method 200 may include determining whether a position of a substrate received by the plurality of substrate-grasping fingers is within a predetermined operational range based on a measurement from the ultrasonic sensor at operation 215. The determination of whether the position of the substrate is in the predetermined operational range may be performed upon confirming that each of the plurality of substrate-grasping fingers is in the closed position. This may be done, for example, by taking a first measurement of a position of the substrate at a first angular position of the substrate and rotor, such as at an angular position that is aligned or substantially aligned with a first one of the substrate-grasping fingers. After taking the first measurement, the rotor and substrate may be rotated to a second angular position, such as a second one of the substrate-grasping fingers. This process may be continued for each of the substrate-receiving fingers. For example, an angular position of the rotor may be adjusted to sequentially align each of the substrate-grasping fingers with the ultrasonic sensor, while taking a measurement at the angular position of each substrate-grasping finger. The positions (e.g., vertical positions) at each location may be compared to one another and/or a predefined range to determine whether the position of the substrate falls within a predetermined operational range.

Upon confirming that each of the plurality of substrate-grasping fingers is in the closed position and that the position of the substrate is within the predetermined operational range, the method 200 may include performing a rinse operation on the substrate. For example, the rotor and substrate may be rotated and a rinse solution may be applied to a surface of the wafer to remove any undesired materials from a surface of the substrate. Upon completion of the rinse operation, the method may include confirming that the position of the substrate is still within the predetermined operational range. Upon confirming that the position of the substrate is still within the predetermined operational range, the method may include moving each of the substrate-grasping fingers to the open position. The rinse system may confirm that each of the substrate-grasping fingers is in the open position. If all of the substrate-grasping fingers are confirmed to be in the open position, the substrate may be from the plurality of substrate-grasping fingers, such as to a processing chamber or other station of a processing system.

In some embodiments, the rinse system may generate an alarm when various operational conditions are not met. For example, an alarm may be generated based on determining that a position of a substrate received by the substrate-grasping fingers is outside the predetermined operational range and/or determining that at least one of the substrate-grasping fingers is in an incorrect position (e.g., closed when supposed to be open or vice versa). The alarm may include an audio and/or video alert that may alert a user that one or more operational conditions have not been met, which may enable the user to address the issue and potentially prevent damage to the substrate and/or rinse assembly.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A substrate rinsing system, comprising:
a rotor;
a plurality of substrate-grasping fingers disposed on the rotor, wherein each of the plurality of substrate-grasping fingers is moveable between an open position and a closed position;
an ultrasonic sensor disposed above the rotor at a position that is radially inward of the plurality of substrate-grasping fingers, the ultrasonic sensor being configured to detect whether a position of a substrate received by the plurality of substrate-grasping fingers is within a predetermined operational range; and
a plurality of reflective sensors, wherein:
each of the plurality of reflective sensors is aligned with a respective one of the plurality of substrate grasping fingers; and
each of the plurality of reflective sensors is configured to detect whether the respective one of the plurality of substrate-grasping fingers is in the open position or the closed position.

2. The substrate rinsing system of claim 1, wherein:
each of the plurality of reflective sensors comprises a beam emitter that emits light and a receiver; and
detecting the respective one of the plurality of substrate-grasping fingers is in the open position or the closed position comprises determining an intensity of the light reflected back from the respective one of the plurality of substrate-grasping fingers and received by the receiver.

3. The substrate rinsing system of claim 2, wherein:
the beam emitter is aligned with a top surface of the respective one of the plurality of substrate-grasping fingers when in the closed position.

4. The substrate rinsing system of claim 1, further comprising:
a plurality of splash guards, wherein each splash guard is positioned about one of the plurality of reflective sensors.

5. The substrate rinsing system of claim 4, wherein:
each splash guard extends at least 0.5 inches below a base of the one of the plurality of reflective sensors.

6. The substrate rinsing system of claim 1, wherein:
the ultrasonic sensor is disposed within an outer 25% of distance from a center of the rotor to the plurality of substrate-grasping fingers.

7. The substrate rinsing system of claim 1, wherein:
the ultrasonic sensor is disposed within an outer 5% of distance from a center of the rotor to the plurality of substrate-grasping fingers.

8. The substrate rinsing system of claim 1, further comprising:
a rinse arm that extends over a rotor, the rinse arm comprising a fluid nozzle that is positioned between the plurality of substrate-grasping fingers.

9. A substrate rinsing system, comprising:
a rotor;
a plurality of substrate-grasping fingers disposed on the rotor, wherein each of the plurality of substrate-grasping fingers is moveable between an open position and a closed position;
an ultrasonic sensor disposed above the rotor at a position that is radially inward of the plurality of substrate-grasping fingers;
a plurality of reflective sensors, wherein each of the plurality of reflective sensors is aligned with a respective one of the plurality of substrate grasping fingers; and
one or more processors that are configured to:
determine whether a position of a substrate received by the plurality of substrate-grasping fingers is within a predetermined operational range based on a measurement from the ultrasonic sensor; and
determine whether the respective one of the plurality of substrate-grasping fingers is in the open position or the closed position based on a signal from each of the plurality of substrate-grasping fingers.

10. The substrate rinsing system of claim 9, wherein the one or more processors are further configured to:
prior to receiving the substrate, confirm that each of the plurality of substrate-grasping fingers is in the open position;
upon receiving the substrate, cause the each of the plurality of substrate-grasping fingers to move to the closed position; and
confirm that each of the plurality of substrate-grasping fingers is in the closed position.

11. The substrate rinsing system of claim 10, wherein the one or more processors are further configured to:
upon confirming that each of the plurality of substrate-grasping fingers is in the closed position, adjust an angular position of the rotor to sequentially align each of the plurality of substrate-grasping fingers with the ultrasonic sensor; and
receive a measurement from the ultrasonic sensor at each angular position of the plurality of substrate-grasping fingers, wherein determining whether a position of a substrate received by the plurality of substrate-grasping fingers is within a predetermined operational range is performed based on the measurements at each angular position of the plurality of substrate-grasping fingers.

12. The substrate rinsing system of claim 11, wherein the one or more processors are further configured to:
upon confirming that each of the plurality of substrate-grasping fingers is in the closed position and that the position of the substrate is within the predetermined operational range, perform a rinse operation on the substrate.

13. The substrate rinsing system of claim 12, wherein the one or more processors are further configured to:
upon completion of the rinse operation, confirm that the position of the substrate is still within the predetermined operational range;
upon confirming that the position of the substrate is still within the predetermined operational range, cause the each of the plurality of substrate-grasping fingers to move to the open position; and
confirm that each of the plurality of substrate-grasping fingers is in the open position.

14. The substrate rinsing system of claim 10, wherein the one or more processors are further configured to:
generate an alarm based on one or both of determining that a position of a substrate received by the plurality of substrate-grasping fingers is outside the predetermined operational range and determining that at least one of the plurality of substrate-grasping fingers is in an incorrect position.

15. A method of rinsing a semiconductor substrate, comprising:
receiving a substrate within a plurality of substrate-grasping fingers of a rotor;
determining whether a position of the substrate is within a predetermined operational range based on a measurement from an ultrasonic sensor disposed above the rotor; and
determining whether the respective one of the plurality of substrate-grasping fingers is in an open position or a closed position based on a signal from each of the plurality of substrate-grasping fingers.

16. The method of rinsing a semiconductor substrate of claim 15, further comprising:
prior to receiving the substrate, confirming that each of the plurality of substrate-grasping fingers is in the open position;
upon receiving the substrate, moving each of the plurality of substrate-grasping fingers to move to the closed position; and
confirming that each of the plurality of substrate-grasping fingers is in the closed position.

17. The method of rinsing a semiconductor substrate of claim 16, further comprising:
upon confirming that each of the plurality of substrate-grasping fingers is in the closed position, adjusting an angular position of the rotor to sequentially align each of the plurality of substrate-grasping fingers with the ultrasonic sensor; and
receiving a measurement from the ultrasonic sensor at each angular position of the plurality of substrate-grasping fingers, wherein determining whether a position of a substrate received by the plurality of substrate-grasping fingers is within a predetermined operational range is performed based on the measurements at each angular position of the plurality of substrate-grasping fingers.

18. The method of rinsing a semiconductor substrate of claim 17, further comprising:
upon confirming that each of the plurality of substrate-grasping fingers is in the closed position and that the position of the substrate is within the predetermined operational range, perform a rinse operation on the substrate.

19. The method of rinsing a semiconductor substrate of claim 18, further comprising:
upon completion of the rinse operation, confirming that the position of the substrate is still within the predetermined operational range;
upon confirming that the position of the substrate is still within the predetermined operational range, moving each of the plurality of substrate-grasping fingers to the open position;
confirming that each of the plurality of substrate-grasping fingers is in the open position; and
transferring the substrate from the plurality of substrate-grasping fingers.

20. The method of rinsing a semiconductor substrate of claim 15, further comprising:
generating an alarm based on one or both of determining that a position of a substrate received by the plurality of substrate-grasping fingers is outside the predetermined operational range and determining that at least one of the plurality of substrate-grasping fingers is in an incorrect position.
